(19) United States
(12) Patent Application Publication
(10) Pub. No.: US 2025/0091896 A1
(43) Pub. Date: Mar. 20, 2025

(54) GAS PHASE TREATMENT METHOD FOR MODIFYING THE SURFACE OF PEROVSKITE MATERIALS

(71) Applicant: NANJING UNIVERSITY OF AERONAUTICS AND ASTRONAUTICS, Nanjing City (CN)

(72) Inventors: Zhuhua ZHANG, Nanjing City (CN); Xiaoming ZHAO, Nanjing City (CN); Bingkun TIAN, Nanjing City (CN); Wanlin GUO, Nanjing City (CN)

(73) Assignee: NANJING UNIVERSITY OF AERONAUTICS AND ASTRONAUTICS, Nanjing City, JS (CN)

(21) Appl. No.: 18/822,529

(22) Filed: Sep. 3, 2024

(30) Foreign Application Priority Data
Sep. 15, 2023 (CN) 2023111898794

(51) Int. Cl. C01G 21/00

(52) U.S. Cl. CPC C01G 21/006; C01P 2002/34

(57) ABSTRACT

The invention relates to a gas phase treatment method for modifying the surface of perovskite materials, which belongs to the field of preparation technology of perovskite material. The details are as follows: the perovskite material is exposed to a hydrogen halide vapor environment at atmospheric pressure. Hydrogen halide can effectively fill the defect sites on the perovskite surface and form stable strong chemical bonds with the perovskite surface. The modified perovskite solar cells based on the invention have enhanced resistance to high temperature, high humidity and strong light. The simulation test shows that the modified photoelectric device can work stably outdoors for nearly 10 years. The invention addresses the issue of poor stability commonly associated with halide perovskite materials, and it offers a low-cost process, which is expected to promote the industrialization and commercialization of perovskite solar cells.

### TECHNICAL FIELD

The invention belongs to the field of preparation technology of perovskite material, specifically relates to a gas phase treatment method for modifying the surface of perovskite materials.

### BACKGROUND ART

Since it was first reported in 2009, the photoelectric conversion efficiency of perovskite solar cells has increased from an initial 3.8% to 26.0%, positioning them as strong contenders for the next generation of photovoltaic technology. Among them, hybrid polycrystalline perovskites prepared by solution treatment processes have attracted wide attention due to their low cost and favorable photoelectric properties. However, the degradation of the perovskite functional layer will cause the output performance of the photoelectric device to be unstable, hindering their practical application.

The degradation of perovskite generally starts from the defect sites on the surface and grain boundaries (such as halide vacancy), which not only leads to the loss of non-radiative charge recombination, but also causes phase separation and induces reactions with the electrodes. Therefore, a simple and effective method for eliminating these defects is crucial to improve the output performance and operational stability of perovskite solar cells. At present, a large number of materials have been developed to modify the defect sites on the perovskite surface. Among them, halide can introduce tunnel junction in the charge extraction layer by binding the defect sites on the surface of perovskite, thereby reducing the non-radiative recombination, and yielding the most efficient perovskite solar cells at present. However, the commonly used solution post-treatment methods are often accompanied by the shortcomings such as harmful solvent residue, limited migration depth of the passivation layer, and uncontrollable reaction rate. Therefore, it is urgent to develop a continuous and quantitative method to control the interface reactions, enabling precise regulation of the halogen composition on the perovskite surface, and then improving the operational stability of perovskite solar cells.

### SUMMARY

In view of the above defects and actual requirements of the current technology, the invention provides a gas phase treatment method for modifying the surface of perovskite materials. The invention aims to utilize the gas phase reactions to fill the defect vacancies at the surface and grain boundaries of the perovskite light-absorption layer in the halide perovskite solar cells, thereby improving the operational stability of the perovskite solar cells.

To achieve the above purpose, the invention provides the following technical scheme:

A gas phase treatment method for modifying the surface of perovskite material comprises the following steps:
S1, heating halide ammonium salts in a sealed environment to expose a perovskite material to a hydrogen halide vapor environment, hydrogen halide effectively fills defect sites on a perovskite surface and forms a stable and strong chemical bond with the perovskite surface.
S2, after reaction, removing the perovskite material and heating it to eliminate residual reactants and impurities to obtain a surface-modified layer.

The invention modifies a perovskite core layer by placing the perovskite material in a hydrogen halide vapor environment under atmospheric pressure, in order to improve an operational stability of perovskite solar cells, the gas phase reactions are used to fill the defect vacancies at the surface and grain boundaries of the perovskite light-absorption layer.

In the above steps, the perovskite material comprises all 2D and 3D halide perovskites.

A structure of 2D halide perovskite is A′ₘAₙ₋₁BₙX₃ₙ₊₁, wherein A′ represents a monovalent or divalent organic cation that separates one group of perovskite layers from another group of perovskite layers, and n is an integer denoting a number of perovskite layers between A′ organic layers. A is one or more of Cs, MA, FA, B is one or more of Pb, Sn, Ge, X is one or more of I, Br, Cl, F.

A structure of 3D halide perovskite is ABX₃, wherein A is one or more of Cs, MA and FA, B is one or more of Pb, Sn and Ge, and X is one or more of I, Br, Cl and F.

Further, in S1, halide ammonium salt comprises of, but is not limited to one or more of ammonium fluoride, ammonium chloride, ammonium iodide, and ammonium bromide.

Further, in S1, a heating temperature must exceed a flash point temperature of corresponding halide ammonium salt.

Further, a thickness of surface modification layer is in a range of 0˜20 nm, and it can be controlled by changing reaction time.

Further, in S1, the reaction time for the perovskite material exposed to the hydrogen halide vapor environment is 1-30 minutes to fully modify the surface defects of the perovskite material.

Further, in S2, a heating temperature is controlled at 50-150° C. to fully remove residual reactants and impurities.

In general, compared with the existing technology, the invention offers the following benefits:
1. Different from the solution post-treatment method with the disadvantages of harmful solvent residues and uncontrollable reaction rates, the gas phase treatment method adopted in this invention has the advantages of continuous reaction and quantitative control, it enables the hydrogen halide vapor continuously and stably fill the defect sites on the surface and grain boundaries of perovskite, forming strong chemical bonds, which solves the issue of poor operational stability of halide perovskite materials at room temperature.
2. The invention utilizes gas phase reaction to modify the perovskite light-absorption layer in the halide perovskite solar cells, so that the halogen ions are filled in the defect sites on the surface and grain boundaries of the perovskite material, which forms strong ionic bonds and effectively inhibits non-radiative recombination, thereby improving the operational stability of the perovskite solar cells in the high temperature, high humidity and strong light conditions. The gas phase treatment method used is simple in operation and low in treatment cost, and it can be applied to modify halide perovskite solar cells on a large scale.
3. Hydrogen halide can effectively fill the defect sites on the perovskite surface and form stable strong chemical bonds. The modified perovskite solar cells based on the invention exhibit enhanced resistance to high temperature, high humidity and strong light, the simulation test indicates that the modified photoelectric device can work stably outdoors for nearly 10 years. The invention addresses the issue of poor stability commonly associated with halide perovskite materials, and it offers a low-cost process, which is expected to promote the industrialization and commercialization of perovskite solar cells.

### BRIEF DESCRIPTION OF THE DRAWINGS

FIG. 1 is the schematic diagram of the gas phase fluorination treatment process for the FAPbI₃ perovskite surface prepared by Embodiment 1 of the invention.

FIG. 2 is the scanning electron microscope (SEM) top view of the perovskite film without gas phase fluorination treatment in Ratio 1 of the invention.

FIG. 3 is the SEM top view of the gas phase fluorination-treated perovskite film in Embodiment 1 of the invention.

FIG. 4 shows the evolution law of the X-ray diffraction (XRD) pattern for the untreated sample at 85° C. with time in Ratio 1 of the invention.

FIG. 5 shows the evolution law of the XRD pattern for the gas phase fluorination-treated sample at 85° C. with time in Embodiment 1 of the invention.

FIG. 6 provides the current-voltage (J-V) curve comparison between the gas phase fluorination-treated and untreated perovskite solar cells in Embodiment 1 and Ratio 1 of the invention.

FIG. 7 shows the performance test result for a large-area (36.3 cm²) perovskite solar module prepared by the method in Embodiment 1 of the invention (the illustration is an optical photo of the solar module).

FIG. 8 shows the device efficiency decay for the encapsulated perovskite solar cells prepared according to Embodiment 1 and Ratio 1 of the invention under the humidity-heat test (i.e., 85° C. and 85% relative humidity).

FIG. 9 shows the device efficiency decay of the unencapsulated perovskite solar cells prepared by Embodiment 1 of the invention and Ratio 1 under the environmental testing conditions (i.e., 25° C. and 60% relative humidity).

FIG. 10 shows the normalized PCE of the treated PSCs plotted against the equivalent operation time under 1-Sun illumination, defined as the aging time (in hours) multiplied by the acceleration factor. The T₈₀ lifetime for the treated PSCs in the plot is approximately 15000 hours, which takes the Nanjing area as an example, the average daily sunlight intensity received is roughly 4 hours of a standard sun illumination. Continuous 15000 hours can be translated to 15000/4=3750 days=10.3 years in the reality.

### DETAILED DESCRIPTION OF THE EMBODIMENTS

In order to make the purpose, technical scheme and effect of the invention more clear, the following embodiments are listed to further explain the invention in detail, it should be pointed out that the specific embodiments described here are only used to explain the invention and are not used to limit the invention.

The following is a detailed description of the technical scheme of the invention in combination with the drawings and the specific implementation methods.

### Embodiment 1

The ITO glass substrate is washed by detergent, acetone and isopropanol (IPA) for 15 minutes respectively, followed by drying with nitrogen and treatment with ultraviolet-ozone for 30 minutes. Then the SnO₂ nanoparticle solution (3 wt %, diluted by water) is spin-coated on the ITO glass substrate at a speed of 3000 rpm and then the substrate is annealed at 150° C. hot plate for 30 minutes. Further, 67 mM KCl aqueous solution is spin-coated at a speed of 5000 rpm for 30 seconds, and annealed at 150° C. hot plate for 15 minutes. After cooling to room temperature, it is treated by ultraviolet-ozone for 30 minutes. Then the 1.5 M PbI₂ solution (the volume ratio of solvent DMF:DMSO is 9:1) is spin-coated on the substrate at a speed of 1500 rpm for 30 seconds, and the substrate is annealed on a 70° C. hot plate for 1 minute and cooled to room temperature. For FAPbI₃ perovskite deposition, the FAI:MACI solution (90 mg: 10 mg dissolved in 1 mL IPA) is spin-coated on the PbI₂ layer at a speed of 2000 rpm for 30 seconds, followed by annealing at 150° C. for 15 minutes. It should be noted that the perovskite layer deposition is carried out at a relative humidity of 35%. After the perovskite deposition, the sample is transferred to a nitrogen-filled glove box for further processing. In the gas phase surface treatment, the perovskite film is exposed to a hydrogen fluoride vapor environment for 1 minute (the hydrogen fluoride vapor environment is produced by heating ammonium fluoride in a sealed environment) and annealed on a 100° C. hot plate for 5 minutes. Subsequently, PTAA (12 mg/mL) is dissolved in toluene, and 6 μl Li-TFSI (340 mg/mL) and 6 μl 4-tert-butylpyridine are added to prepare PTAA solution. The PTAA solution is spin-coated on the perovskite film after gas phase surface treatment at a speed of 3000 rpm for 30 seconds to obtain a hole transport layer. Finally, a gold electrode with the thickness of 100 nm is evaporated onto the sample to complete the perovskite solar cells.

### Ratio 1.

The present ratio is basically the same as Embodiment 1, the difference is that no gas phase surface treatment is performed in Ratio 1.

### Embodiment 2

The ITO glass substrate is washed by detergent, acetone and isopropanol for 15 minutes respectively, followed by drying with nitrogen and treatment with ultraviolet-ozone for 30 minutes. Then the SnO₂ nanoparticle solution (3 wt %, diluted in water) is spin-coated on the ITO glass substrate at a speed of 3000 rpm and then the substrate is annealed at 150° C. hot plate for 30 minutes. Further, 67 mM KCl aqueous solution is spin-coated on the substrate at a speed of 5000 rpm for 30 seconds, and then the substrate is annealed at 150° C. hot plate for 15 minutes. After cooling to room temperature, it is treated by ultraviolet-ozone for 30 minutes. Then the 1.5 M PbI₂ solution (volume ratio of solvent DMF:DMSO is 9:1) is spin-coated on the substrate at a speed of 1500 rpm for 30 seconds, and the substrate is annealed at 70° C. for 1 minute and then cooled to room temperature. For CsPbI₃ perovskite deposition, the CsI solution (10 mg dissolved in 1 mL IPA) is spin-coated on the PbI₂ layer at a speed of 500 rpm for 30 seconds, followed by annealing at 350° C. for 15 minutes. It should be noted that the perovskite layer deposition is carried out at a relative humidity of 35%. After the perovskite deposition, the sample is transferred to a nitrogen-filled glove box for further processing. During the gas phase surface treatment, the perovskite film is exposed to a hydrogen fluoride vapor environment for 1 minute (the hydrogen fluoride vapor environment is produced by heating ammonium fluoride in a sealed environment) and annealed at 100° C. for 5 minutes. Subsequently, PTAA (12 mg/mL) is dissolved in toluene, and 6 μl Li-TFSI (340 mg/mL) and 6 μl 4-tert-butylpyridine are added to prepare PTAA solution. The PTAA solution is spin-coated on the perovskite film after gas phase surface treatment at a speed of 3000 rpm for 30 seconds to obtain a hole transport layer. Finally, a gold electrode with the thickness of 100 nm is evaporated onto the sample to complete the perovskite solar cells.

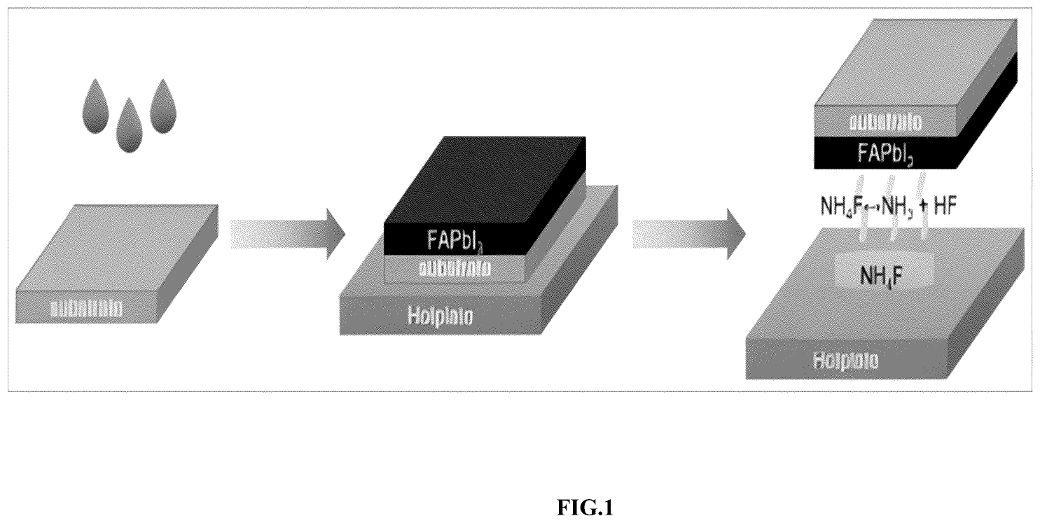

The specific test results are as follows: FIG. 1 is the schematic diagram of the gas phase fluorination treatment process for FAPbI₃ perovskite surface prepared by Embodiment 1 of the invention. Firstly, FAPbI₃ perovskite film is formed on the substrate, and then it is reacted in HF gas to modify the perovskite surface.

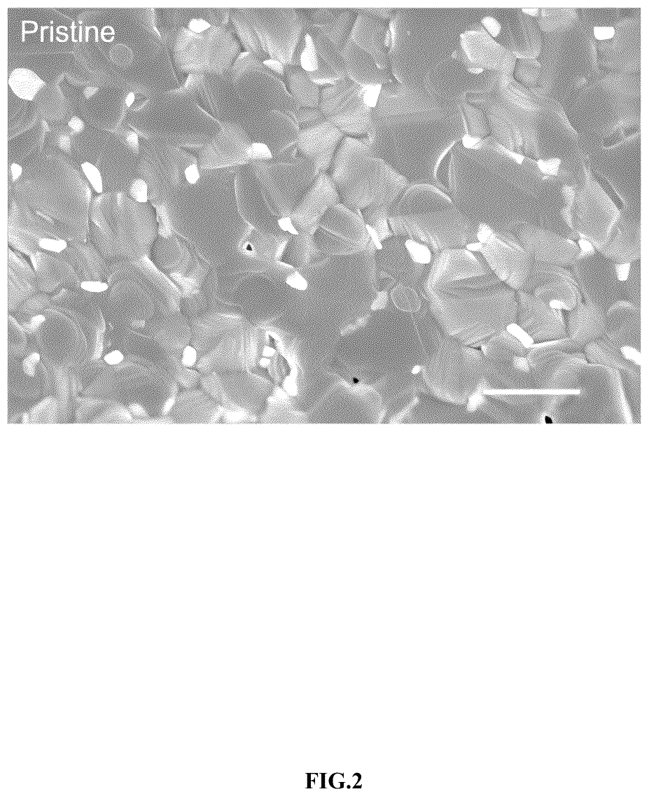

FIG. 2 is the SEM top view of the perovskite film without gas phase fluorination treatment in Ratio 1 of the invention. The image shows that the pristine perovskite film has bright PbI₂ clusters and a small amount of holes.

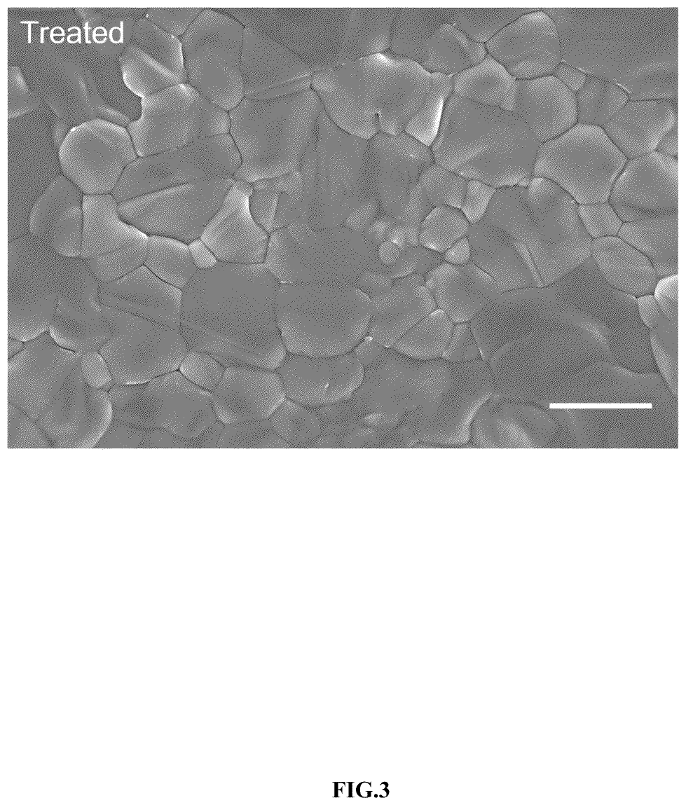

FIG. 3 is the SEM top view of the perovskite film after gas phase fluorination treatment in Embodiment 1 of the invention. The image shows that the PbI₂ clusters and holes on the surface of the perovskite film are significantly reduced after the gas phase fluorination treatment.

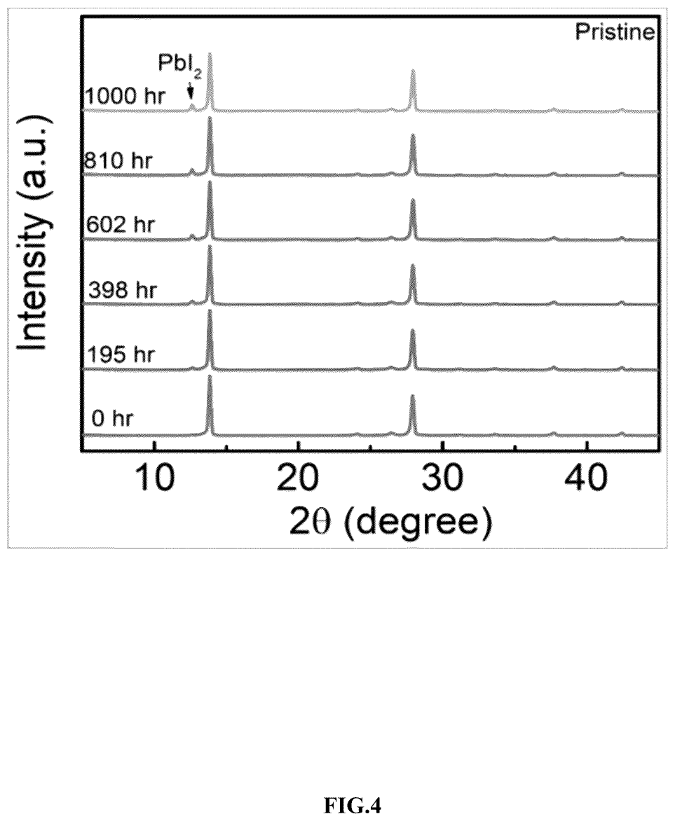

FIG. 4 shows the evolution law of XRD pattern for the untreated sample at 85° C. with time in Ratio 1 of the invention. After 1000 hours of aging, the (001) diffraction peak of the original sample PbI₂ is significantly enhanced, and the relative intensity reaches 12% of the (100) peak intensity of FAPbI₃, indicating that FAPbI₃ degrades seriously.

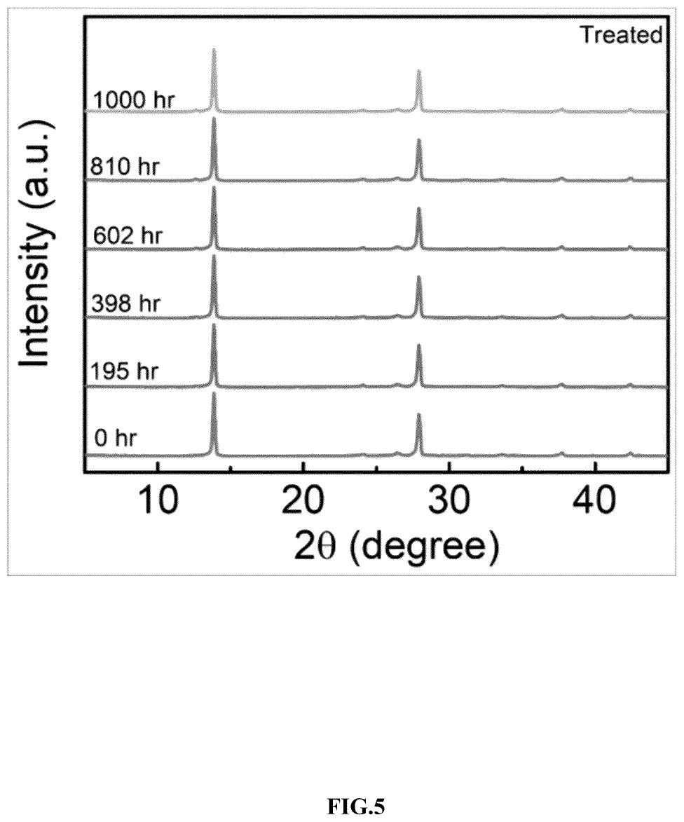

FIG. 5 shows the evolution law of the XRD pattern for the gas phase fluorination-treated sample at 85° C. with time in Embodiment 1 of the invention. After 1000 hours of aging, the (001) diffraction peak intensity of PbI₂ is only 3% of the (100) diffraction peak intensity of FAPbI₃, indicating that the gas phase fluorination treatment can effectively inhibit the perovskite degradation.

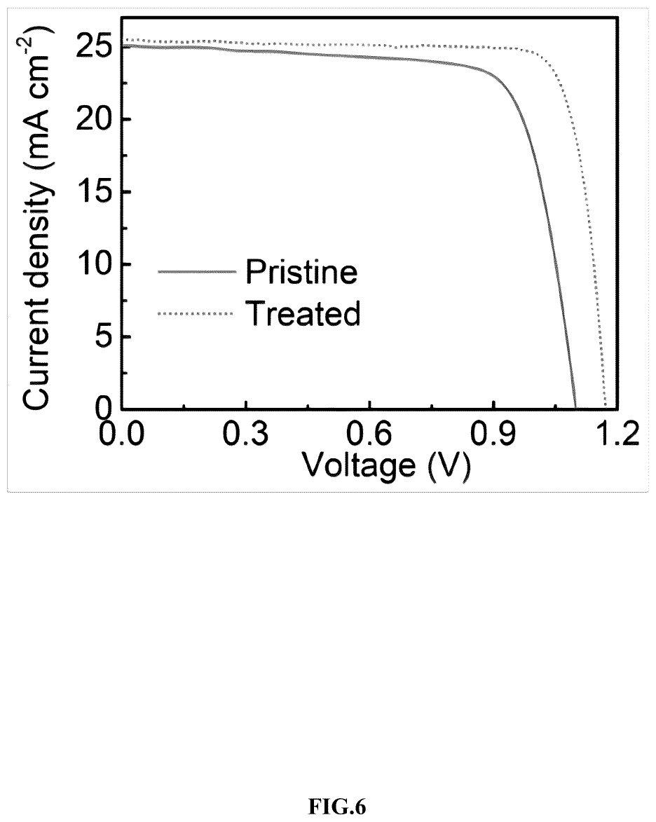

FIG. 6 provides the J-V curve comparison between the gas phase fluorination-treated and pristine perovskite solar cells in Embodiment 1 and Ratio 1 of the invention. The open-circuit voltage (V_{OC}), short-circuit current density (J_{SC}), fill factor (FF) and power conversion efficiency (PCE) of the pristine PSC are 1.10 V, 25.1 mA cm⁻², 0.76 and 21.0% respectively. In contrast, the V_{OC} and J_{SC} of the treated PSC are increased to 1.17 V and 25.5 mAcm⁻² respectively, with the FF of 0.83 and PCE of 24.8%.

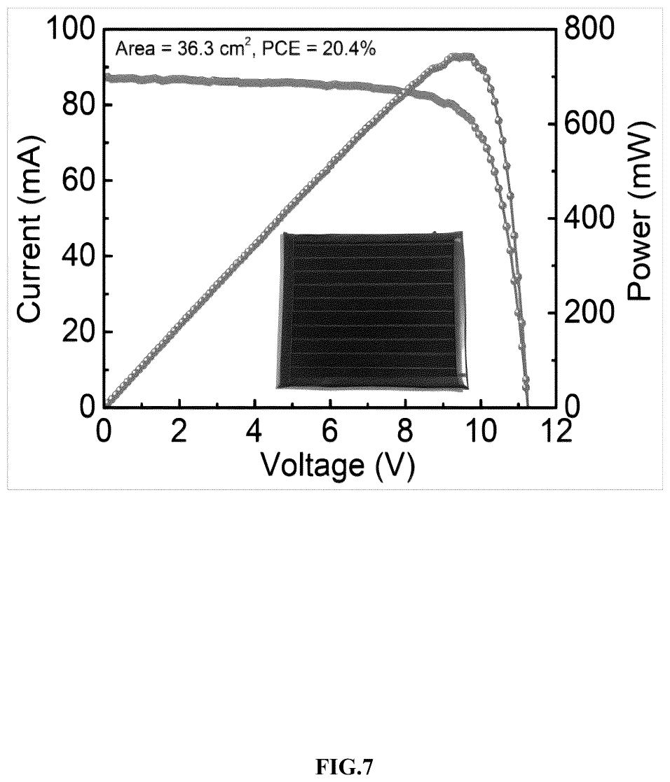

FIG. 7 shows the performance test result of a large-area (36.3 cm²) perovskite solar module prepared by the method of Embodiment 1 of the invention (the illustration is an optical photograph of the solar module). The V_{OC} and I_{SC} of the perovskite solar module are 11.2 V and 87 mA respectively, and the FF and PCE are 0.76 and 20.4% respectively.

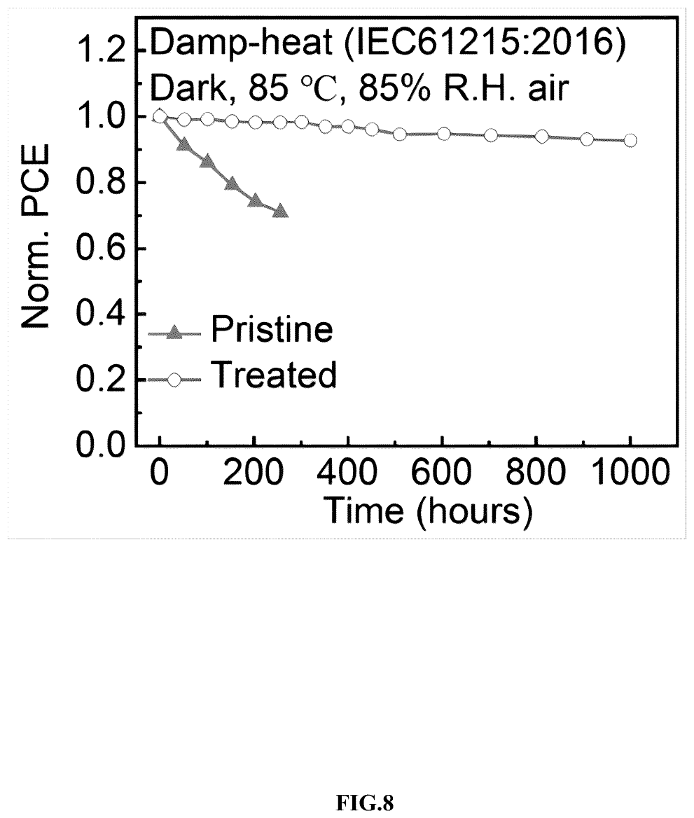

FIG. 8 shows the device efficiency decay for the encapsulated perovskite solar cells prepared by Embodiment 1 and Ratio 1 of the invention under the humidity-heat test (i.e., 85° C. and 85% relative humidity). The PCE of pristine PSC decreases by over 20% after 200 hours of operation. However, the gas phase fluorination-treated PSC still maintains over 80% of the initial PCE after 1000 hours, which indicates that gas phase fluorination treatment enhances the operational stability of PSCs in the high temperature and high humidity environments.

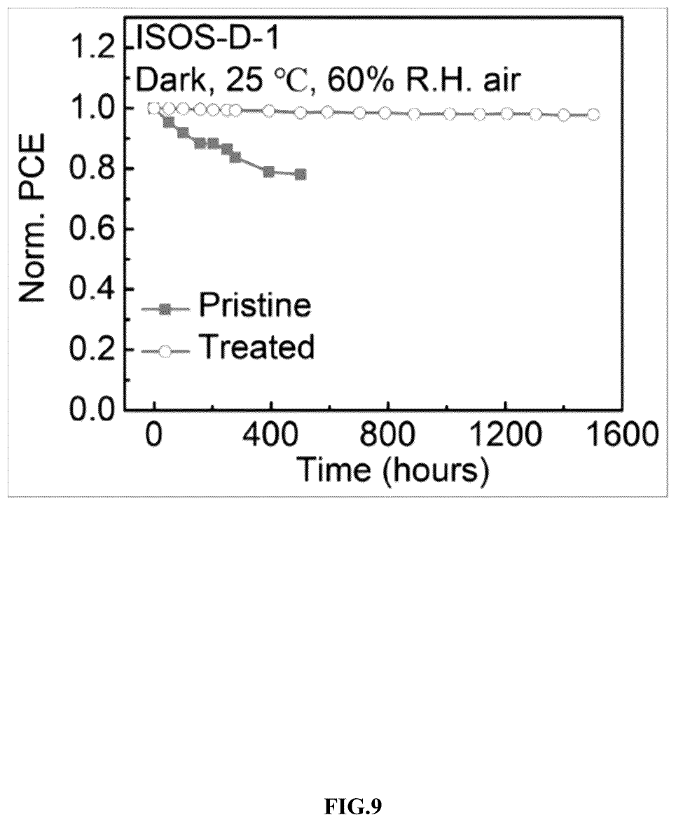

FIG. 9 shows the device efficiency decay of the unencapsulated perovskite solar cells prepared by Embodiment 1 of the invention and Ratio 1 under the environmental test (i.e., 25° C. and 60% relative humidity) conditions. After 400 hours of operation, the PCE decay of pristine PSC is more than 20%, while the PCE of treated PSC is still over 90% of the initial value after 1500 hours of operation.

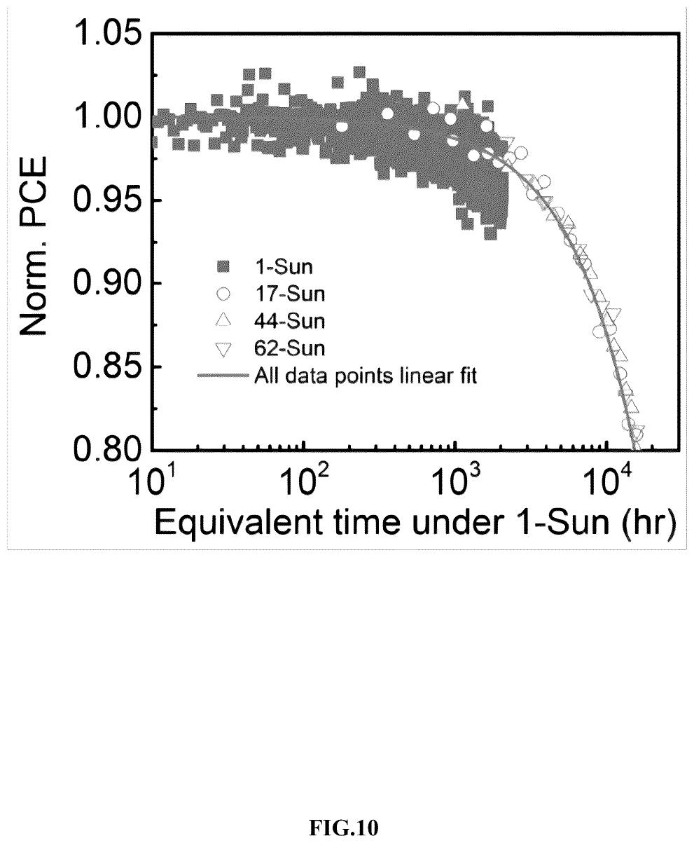

FIG. 10 shows the normalized PCE of the treated PSCs plotted against the equivalent operating time under 1-sun illumination, which is defined as the aging time (in hours) multiplied by the acceleration factor. The T₈₀ lifetime for the treated PSCs in the plot is approximately 15000 hours, in real life, which takes the Nanjing area as an example, the average daily sunlight intensity received is roughly 4 hours of a standard sun illumination. Continuous 15000 hours can be translated into 15000/4=3750 days=10.3 years in the reality.

### Embodiment 3

The ITO glass substrate is washed by detergent, acetone and isopropanol for 15 minutes respectively, after it is dried by nitrogen, it is treated by ultraviolet-ozone for 30 minutes. Then the C₆₀ thin film (1 mg/mL, diluted in DCB) is spin-coated on the ITO glass substrate at a speed of 3000 rpm and the substrate is annealed at 80° C. for 30 minutes. Further, 67 mM KCl aqueous solution is spin-coated on the substrate at a speed of 5000 rpm for 30 seconds, and the substrate is annealed at 150° C. for 15 minutes. After cooling to room temperature, it is treated by ultraviolet-ozone for 30 minutes. Then the 1.35 M methylammonium iodide (MAI) and PbI₂ are dissolved in DMF:NMP (volume ratio of solvent DMF:DMSO is 95:5), after that, the solution is spin-coated on the substrate at a speed of 1500 rpm for 30 seconds, and the substrate is annealed on a 150° C. hot plate for 15 minutes. It should be noted that the perovskite layer deposition is carried out at a relative humidity of 35%. After the perovskite deposition, the sample is transferred to a nitrogen-filled glove box for further processing. During the gas phase surface treatment, the perovskite film is exposed to a hydrogen fluoride vapor environment for 1 minute (the hydrogen fluoride vapor environment is produced by heating ammonium fluoride in a sealed environment) and annealed at 100° C. for 5 minutes. Subsequently, WO₃ solution (2 wt % in isopropanol) is prepared and spin-coated onto the perovskite film at a speed of 3000 rpm for 30 seconds, followed by annealing at 50° C. for 5 minutes to form a hole transport layer. Finally, a gold electrode with the thickness of 100 nm is evaporated onto the sample to complete the perovskite solar cells.

### Embodiment 4

The ITO glass substrate is washed by detergent, acetone, and isopropanol for 15 minutes respectively, after it is dried by nitrogen, it is treated by ultraviolet-ozone for 30 minutes, and then the PEDOT:PSS film is deposited. For the preparation of FASnI₃ perovskite film, the perovskite precursor composed of 1 M SnI₂, 1 M FAI and 0.1 M SnF₂ is first stirred in DMSO at room temperature for 2 hours. The precursor solution is spin-coated on the substrate at a speed of 1000 rpm for 12 seconds, and then it is spin-coated on the substrate at a speed of 5000 rpm for 48 seconds. At the 30th second of the second step, 80 μL of chlorobenzene is spin-coated onto the perovskite film. Then perovskite film is annealed at 60° C. and 100° C. for 10 seconds and 12 minutes respectively. In the gas phase surface treatment, the perovskite film is exposed to a hydrogen fluoride vapor environment for 1 minute (hydrogen fluoride vapor environment is produced by heating ammonium fluoride in a sealed environment) and annealed on a 100° C. hot plate for 5 minutes. Finally, the perovskite solar cells after gas phase surface treatment can be completed by evaporating C₆₀ (60 nm), BCP (8 nm) and Ag electrode (70 nm) in a high vacuum environment.

The above are only the preferred implementation methods of the invention, it should be pointed out that for the ordinary technicians in the technical field, some improvements can be made without breaking away from the principle of the invention, and these improvements should also be regarded as the protection scope of the invention.

What is claimed is:

1. A gas phase treatment method for modifying the surface of perovskite materials, which comprises the following steps:
S1, heating halide ammonium salts in a sealed environment to expose a perovskite material to a hydrogen halide vapor environment, hydrogen halide effectively fills defect sites on a perovskite surface and forms a stable and strong chemical bond with the perovskite surface;
S2, after reaction, removing the perovskite material and heating it to eliminate residual reactants and impurities to obtain a surface-modified layer.

2. The gas phase treatment method for modifying the surface of perovskite materials according to claim 1, the perovskite material comprises all 2D and 3D halide perovskites; a structure of 2D halide perovskite is A′ₘAₙ₋₁BₙX₃ₙ₊₁, wherein A′ represents a monovalent or divalent organic cation that separates one group of perovskite layers from another group of perovskite layers, and n is an integer representing a number of perovskite layers between A′ organic layers; A is one or more of Cs, MA, FA, B is one or more of Pb, Sn, Ge, X is one or more of I, Br, Cl, F; a structure of 3D halide perovskite is ABX₃, wherein A is one or more of Cs, MA and FA, B is one or more of Pb, Sn and Ge, and X is one or more of I, Br, Cl and F.

3. The gas phase treatment method for modifying the surface of perovskite materials according to claim 1, halide ammonium salt comprises of, but is not limited to one or more of the ammonium fluoride, ammonium chloride, ammonium iodide, and ammonium bromide.

4. The gas phase treatment method for modifying the surface of perovskite materials according to claim 1, in S1, a heating temperature must exceed a flash point temperature of corresponding halide ammonium salt.

5. The gas phase treatment method for modifying the surface of perovskite materials according to claim 1, in S1, a reaction time for the perovskite material exposed to the hydrogen halide vapor environment is 1-30 minutes to fully modify the surface defects of the perovskite material.

6. The gas phase treatment method for modifying the surface of perovskite materials according to claim 1, a thickness of surface-modified layer is in a range of 0˜20 nm, and it can be controlled by changing reaction time of S1.

7. The gas phase treatment method for modifying the surface of perovskite materials according to claim 1, in S2, a heating temperature is controlled at 50-150° C. to fully remove residual reactants and impurities.

8. A perovskite solar cell prepared by the gas phase treatment method for modifying the surface of perovskite materials according to claim 1.

9. The gas phase treatment method for modifying the surface of perovskite materials according to claim 8, a gas phase reaction is used to modify a perovskite light-absorption layer in halide perovskite solar cells, so that halogen ions are filled on the surface of the perovskite material and defect sites at grain boundaries, which form strong ion bonds and effectively inhibit non-radiative recombination, thereby improving the operational stability of the perovskite solar cells in an environment with high temperature, high humidity and strong light.
